(19) United States
(12) Patent Application Publication
(10) Pub. No.: US 2006/0042683 A1
(43) Pub. Date: Mar. 2, 2006

(54) System and method for mounting photovoltaic cells

(76) Inventor: Ron Gangemi, Nevada City, CA (US)

Correspondence Address: BERNHARD KRETEN;WEINTRAUB GENSHLEA CHEDIAK SPROULE, 400 CAPITOL MALL, 11TH FLOOR, SACRAMENTO, CA, 95814, US

(21) Appl. No.: 10/931,183

(22) Filed: Aug. 31, 2004

(51) Int. Cl. H01L 31/00

(52) U.S. Cl. 136/252; 136/253

(57) ABSTRACT

A system for mounting photovoltaic cells on a surface and utilizing the energy produced therefrom. Several cells are connected in series to produce DC power. The DC power is converted to AC power suitable for use in utility lines. The cells are pigmented to ensure efficient collection of available radiation.

### FIELD OF THE INVENTION

The following invention is generally related to instrumentalities and methodologies in photovoltaic cells. More specifically, the instant invention is directed to a method and apparatus for mounting photovoltaic cells on a surface, such as a roof or wall.

### BACKGROUND OF THE INVENTION

Photovoltaic (PV) cells are growing in popularity as an alternative energy source as power costs increase. Owners of commercial and residential buildings are installing PV cells to reduce overall dependence on energy provided by a utility company. Owners of residential property are often concerned with curb appeal and generally find current PV systems unattractive. Current systems tend to be more fragile than desired and difficult to install. The number of panels that must be used to provide enough power also creates potential wiring issues with respect to connections that must be made with existing utility systems. The need exists for an integrated, less complicated system that is pleasing to the eye, yet capable of producing power at desired levels.

The following prior art reflects the state of the art of which applicant is aware and is included herewith to discharge applicant's acknowledged duty to disclose relevant prior art. It is stipulated, however, that none of these references teach singly nor render obvious when considered in any conceivable combination the nexus of the instant invention as disclosed in greater detail hereinafter and as particularly claimed.

| PAT. NO. | ISSUE DATE | INVENTOR |
|---|---|---|
| 6,360,497 | Mar. 26, 2002 | Nakazima et al. |
| 6,476,314 | Nov. 5, 2002 | Bauman et al. |
| 2002/0166580 | Nov. 14, 2002 (published) | Bauman et al. |
| WO 01/75377 A1 | Oct. 11, 2001 (published) | Erling |
| WO 02/101839 A1 | Dec. 19, 2002 (published) | Mucci |
| EP 1296382 A1 | Mar. 26, 2003 (published) | Gambale Srl |

### SUMMARY OF THE INVENTION

The present invention is distinguishable over the prior art in that a plurality of photovoltaic cells are oriented together as a panel of cells on a frame, which is then mounted on a surface. The positive and negative connectors from each frame run through a channel on the frame into a combiner box that has one pair of wires as an output. Multiple combiner boxes may be used with a recombiner to ensure that there is only one output, regardless of the number of cells. In addition, the cells themselves may have a coating that maximizes energy production by providing enhanced absorption of available radiation.

### OBJECTS OF THE INVENTION

Accordingly, it is a primary object of the present invention to provide a new and novel device and method for efficient capture of available radiation.

It is a further object of the present invention to provide a device and method as characterized above that is modular in nature and provides for relatively uncomplicated installation.

It is a further object of the present invention to provide a device and method as characterized above that converts captured radiation into electricity suitable for utilization with conventional utility lines.

Viewed from a first vantage point, it is an object of the present invention to provide a system for converting actinic radiation to another form of energy, comprising, in combination: a roof; a frame; a panel sensitive to the actinic radiation; means to mount the frame atop the roof; means to mount the panel to the frame, the frame exposed to the actinic radiation; and means to transfer energy from the panel through a chaseway on the frame thence to a power network.

Viewed from a second vantage point, it is an object of the present invention to provide a method for converting actinic radiation to another form of energy, the steps including: forming a panel by connecting a plurality of photovoltaic cells, the panel of photovoltaic cells having a plurality of electrical tabs exiting the panel, each electrical tab attached to a separate connection wire, each of the connection wires travelling from the panel perpendicular to an edge of the panel and further travelling through a clip that directs the connection wires to separate locations; lodging the panel in a frame, the frame comprising a recess to receive the panel, separate paths for each connection wire, a hood adjacent the recess to receive the clip, and means to receive and direct the connection wires along an edge of the frame, the panel and frame comprising a tile; electrically interconnecting a plurality of tiles; imbricating a plurality of the interconnected tiles on a surface exposed to actinic radiation; combining output from the interconnected tiles; and feeding the combined output into a power network.

Viewed from a third vantage point, it is an object of the present invention to provide an apparatus for converting actinic radiation to another form of energy, comprising, in combination: a plurality of photovoltaic cells, the photovoltaic cells electrically interconnected with one another and oriented into a panel, wherein output from the panel is directed through a plurality of electrical tabs, the electrical tabs attached to a plurality of connection wires to direct output from the panel, the connection wires routed through a clip; and a frame, the frame comprising, in combination: a recess to receive the panel such that a surface of the panel not contacting the frame is planar with respect to a non-recessed portion of the frame, the recess formed by a plurality of cross pieces, the cross pieces defining windows in the frame; a mounting portion on an edge of the non-recessed portion of the frame, the mounting portion having means to mount a combined frame and panel to a surface; a plurality of separate paths, each path to receive one connection wire from the panel; and a hood to receive the clip from the panel.

Viewed from a fourth vantage point, it is an object of the present invention to provide an apparatus for converting actinic radiation to another form of energy, comprising, in combination: a plurality of photovoltaic cells oriented in a panel, the panel having means to output current through connection wires; a frame, the frame comprising, in combination: a recess to receive the panel; mounting means to mount the frame on a surface, the mounting means on a separate portion of the frame than the recess; means to separate and direct the connection wires away from the panel; and clip means to selectively attach one frame to another frame.

These and other objects will be made manifest when considering the following detailed specification when taken in conjunction with the appended drawing figures.

### BRIEF DESCRIPTION OF THE DRAWINGS

FIG. 1 is an exploded view of the laminate structure according to the present invention.

FIG. 2 is a depiction of the present invention on a conventional roof.

FIG. 3 is a detail view of the frame interconnection shown in FIG. 2.

FIG. 4 is a front view of a panel having ten photovoltaic cells.

FIG. 5 is a front view of a panel having twelve photovoltaic cells.

FIG. 6 is a front view of a panel having twenty-four photovoltaic cells.

FIG. 7 is a detail view of the frame.

FIG. 7A is a cutaway view of a fastener hole in the frame shown in FIG. 7.

FIG. 8 is a perspective view of the attachment of the wind loading clip.

FIG. 9 is a detail view of the wind loading clip.

FIGS. 10 and 11 are perspective views of the connection of two frames using the wind loading clips.

FIG. 12 is a side view of the connection shown in FIG. 11.

FIG. 13 is a representation of the conversion and delivery system used in the present invention.

### DESCRIPTION OF PREFERRED EMBODIMENTS

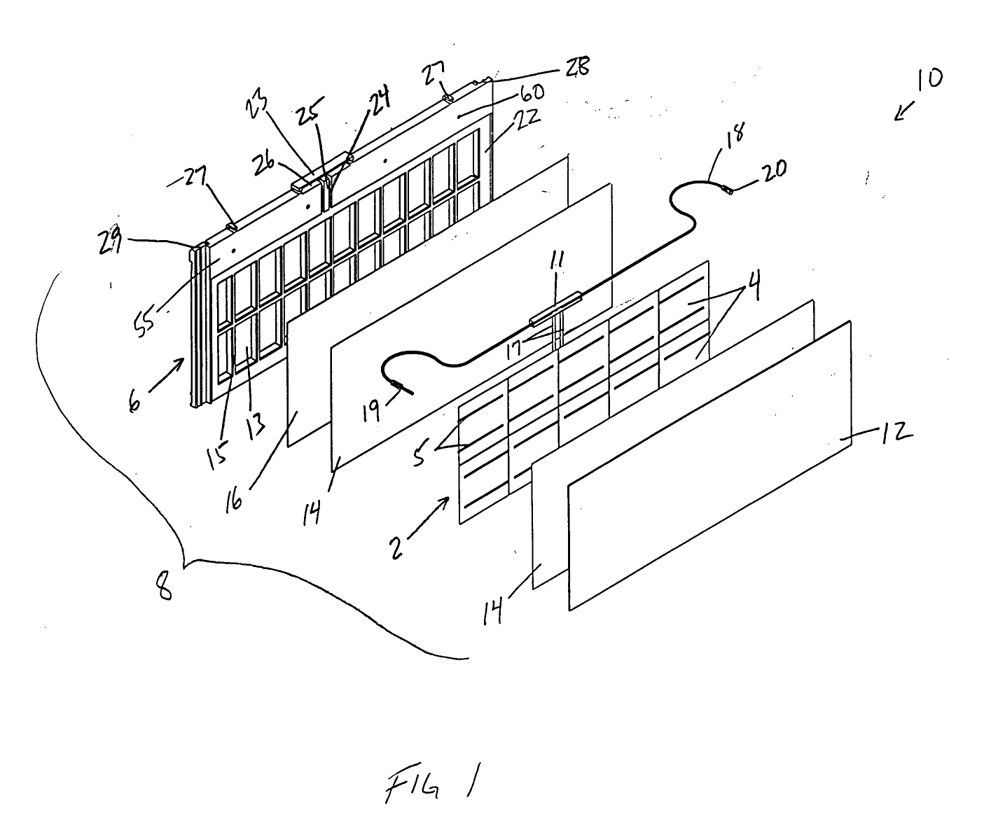

Considering the drawings, wherein like reference numerals denote like parts throughout the various drawing figures, reference numeral 10 as shown in FIG. 1 is directed to the system according to the present invention.

In its essence, the system 10 includes a panel 2 of photovoltaic cells 4 mounted in a frame 6.

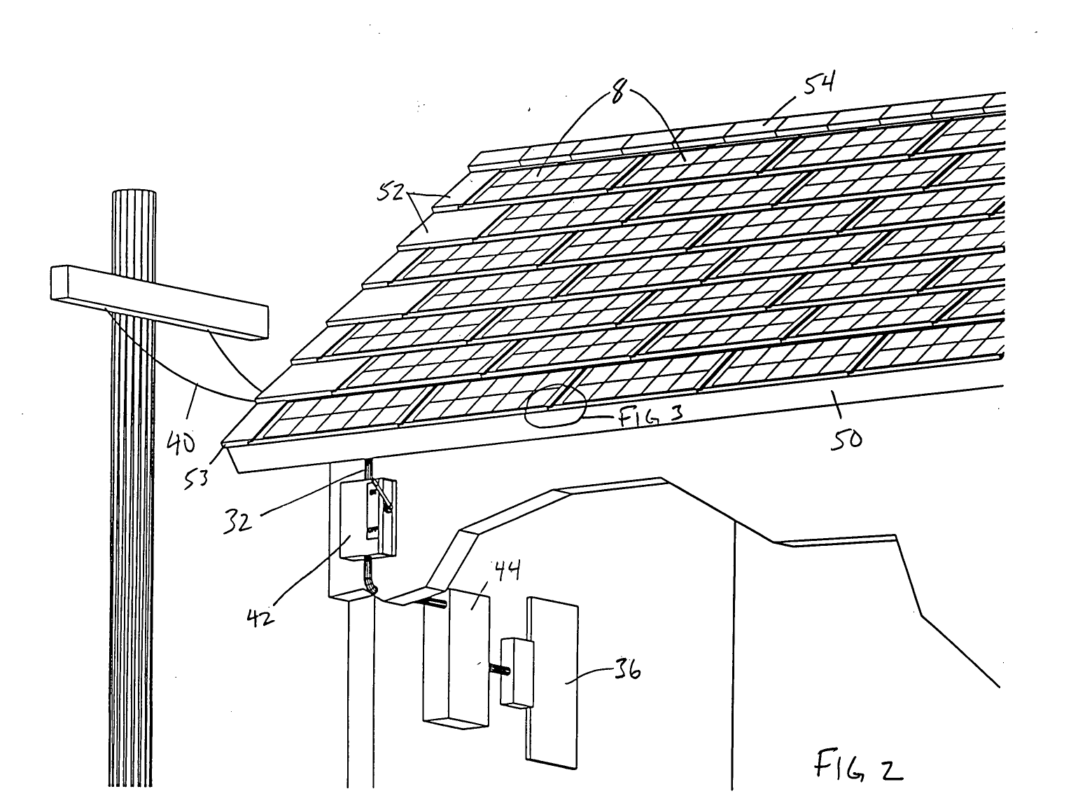

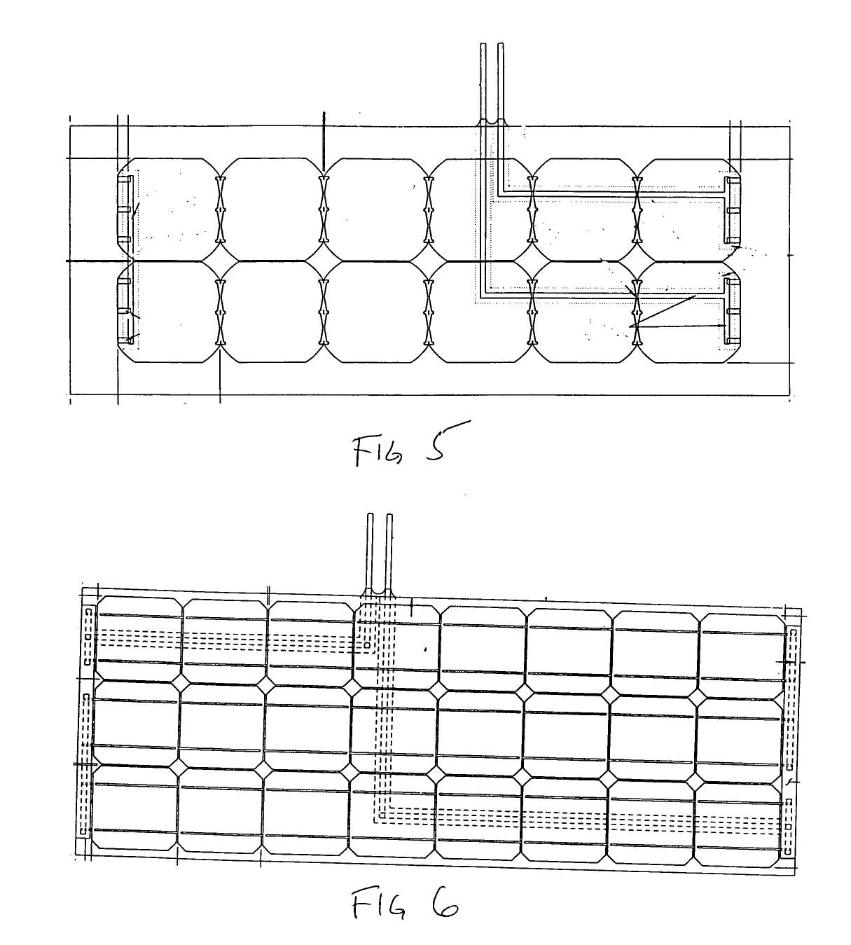

Several cells 4, preferably twelve, are electrically connected in series to each other. Ten cells 4 are shown in FIGS. 1 and 2, and combinations of ten, twelve and twenty-four cells 4 are shown in FIGS. 4-6. The panel 2 is the same size in each case; it is the cells 4 that change in size. Each cell 4 has its own set of connection wires 5 to direct current away from the cells 4. The cells 4 are utilized in a panel 2 that is a laminate support structure. Referring to FIG. 1, the support is preferably constructed in layers, with a layer of ethyl-vinyl acetate 14 on either side of and adjacent to the cells 4, a glass outer sheet 12 adjacent the other side of one ethyl-vinyl layer 14, and an aluminum heat sink 16 adjacent the side remote from the glass outer sheet. Electrical tabs 17 extend from one edge of the panel 2. The tabs 17 are soldered onto a pair of electrical cables 18 having male and female connectors 19 and 20 respectively. The electrical cables 18 are directed from the tabs 17 through an elongate U-shaped channel-like clip 11 for direction away from the panel 2.

The panel 2 nests within a frame 6 having an recessed portion 22 to accept the panel 2. The recessed portion 22 also contains several windows 13 separated by spines 15. Twenty-two windows 13 are illustrated, but any number of windows 13 may be present. The panel 2 is oriented in the frame 6 with the aluminum heat sink 16 contacting the recessed portion 22 of the frame 6, adjacent the window 13 and spine 15 area.

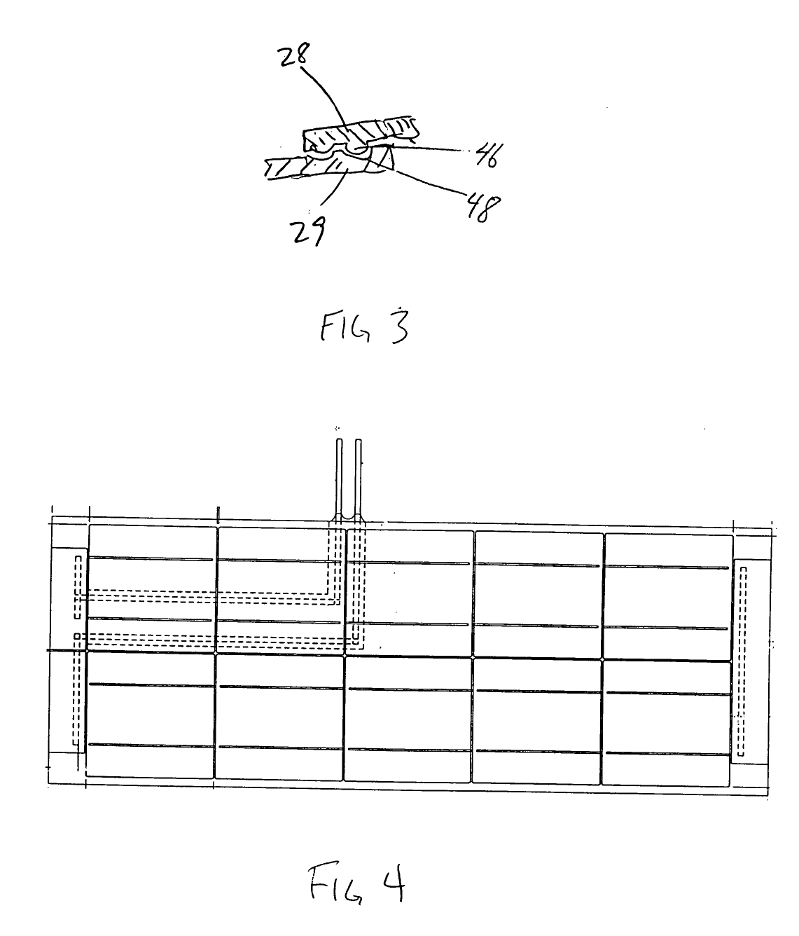

The frame 6 includes a hood 23 that frictionally receives clip 11. Paths 24 receive tabs 17; a separator 25 holds the tabs 17 in spaced relation. A chaseway 26 accepts and directs the electrical cables 18 from the panel 2. The tabs 17 each have a separate path 24, divided by the separator 25 to prevent contact. The channel-like clip 11 snaps into the hood 23 for precise placement. The electrical cables 18 are further directed through constraining clips 27 for correct orientation. As a unit, the panel 2 and frame 6 form a tile 8. The tile 8 may be mounted to a surface 50, preferably a roof, where the cells 4 are exposed to actinic radiation. The tiles 8 are equipped with complementarily formed ends 28,29 that allow adjacent tiles 8 to slide together using a groove 46 and tongue 48 method (see FIG. 3).

Referring to FIGS. 7 and 7A, a plurality of circular fastener holes 60, preferably four, are located on the windowless portion 55 of the frame 6. Each hole 60 is preferably circumscribed by a plurality of concentric grooved portions 62,64 alternating with a ringed portion 68, with the fastener hole 60 located at the lowest central point therein. The grooved portions 62,64 are grooves relative to the plane of the surface of the windowless portion 55 of the frame 6; that is, the grooves are recessed into the frame 6. The hole 60 is first circumscribed by a chamfered edge 66, when is then circumscribed by a first groove 62. A ringed portion 68 circumscribes the first groove 62. The top of the ringed portion 68 is in the same plane as the surface of the windowless portion 55 of the frame 6. A second groove 64 circumscribes the ringed portion 68. The second groove 64 is preferably recessed an identical amount as the first groove 62. The recesses allow tiles 8 to be imbricated such that a lowest R₁ has a portion 55 that underlies a second, higher row R₂, going up to the roof apex.

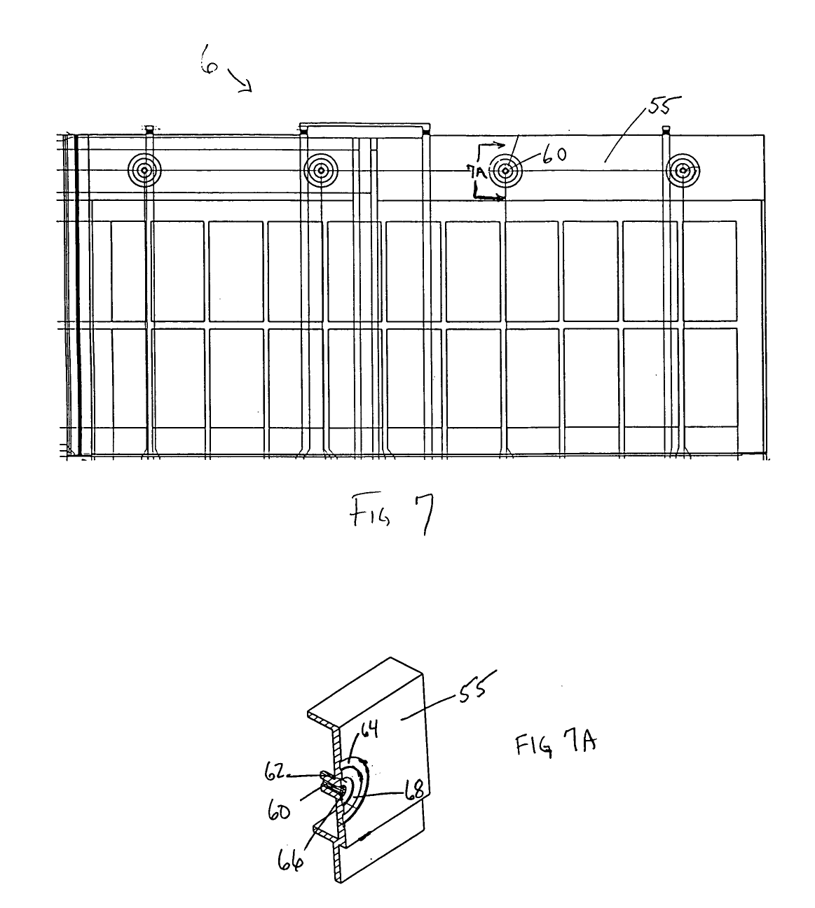

Referring to FIG. 8, the holes 60 receive mounting screws 70 and can also secure optional wind loading clips 72. Anti-rotational ribs 74 are located on the portion 55 of the frame 6 on either side of the wind loading clips 72, as shown in FIG. 9, to help locate the clips on the frame 6.

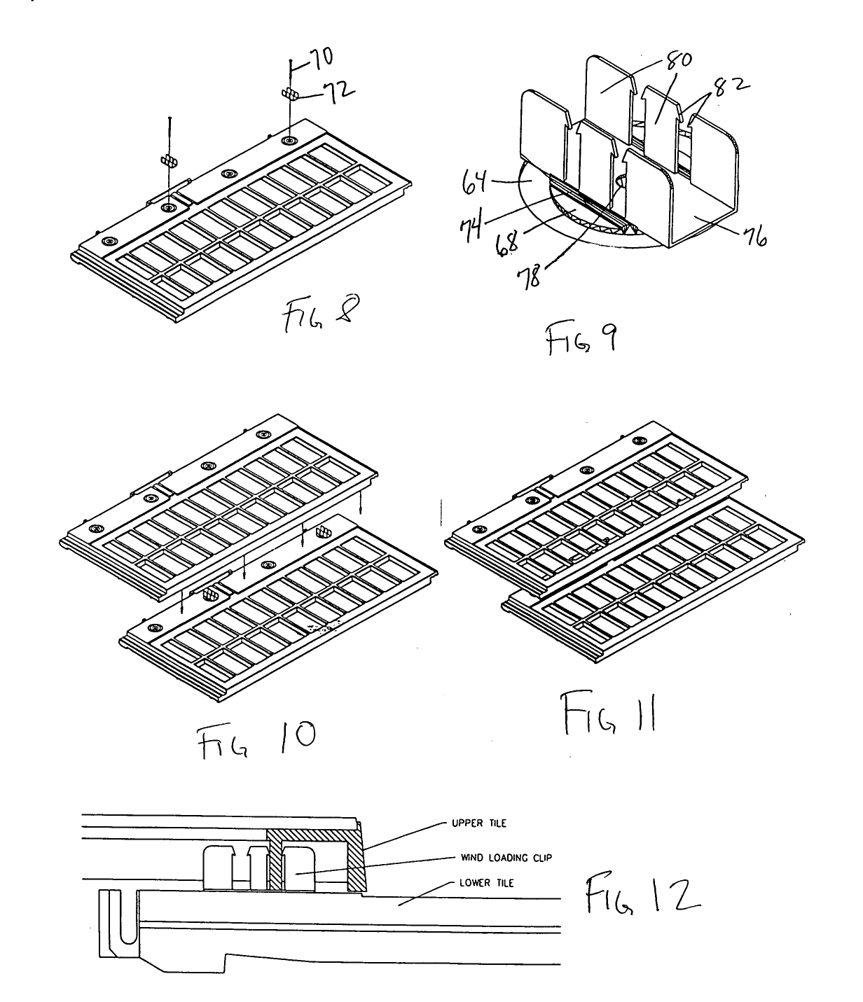

The wind loading clips 72 have a planar, preferably rectangular, bottom portion 76 and a centrally located screwbore 78. The screwbore is placed directly over the hole 60, and the bottom portion 76 rests across the circumscribing grooves 62,64 and ringed portion 68, located by the ribs 74. From the bottom portion 76, the wind loading clip 72 extends upwardly on either side along the long axis to form teeth 80. Each of the teeth 80 has endprongs 82 that allow multiple frames 6 to be interlocked with one another (FIGS. 10,11,12). This interlocking produces an offset, overlapping shingle-type array.

Anti-rotational ribs 74 are formed on either side of each wind loading clip 72 on portion 55, utilizing the grooves 62,64 and ringed portion 68. The ribs 74 prevent the wind loading clips from moving. Specifically, rotational movement of the wind loading clip 72 about the mounting screw 70 is prevented to ensure a stable structure when frames 6 are joined together and held by the endprongs 82, as shown in FIG. 12.

The cells 4 can be aesthetically color coordinated with the building and exhibit a range of pigmentation while still capturing as much radiation from the available spectrum of light as possible. Specifically, the cells 4 typically exhibit blue or gray color, using conventional photocells, which has been shown to provide efficient conversion of the full range of radiation. In addition, however, the files 8 may exhibit a red color by using pink colored glass 12, which maintains efficient conversion of radiation.

Several tiles 8, preferably eleven, are connected in series with one another via male and female connectors 19,20 to form a string of files 8. Strings of files 8 are mounted on the surface 50, preferably a roof. At the edge of the surface 50, an edge piece 52 is placed, then a string of files 8. The edge pieces 52 are available in different widths to produce pattern of files 8 that are offset from one another, as shown in FIG. 2. The end of the edge piece 52 that engages the tile 8 is equipped with the same type of sliding end 28,29 as the tiles 8. The remote end 53 of the edge piece 52 may end flush with the edge of the surface 50, or it may exhibit an overhang relative to the edge of the surface 50. Peaked portions of a surface 50 are covered with cap blocks 54. The cap blocks 54 are capable of connecting to the frames 8 or to the roof itself.

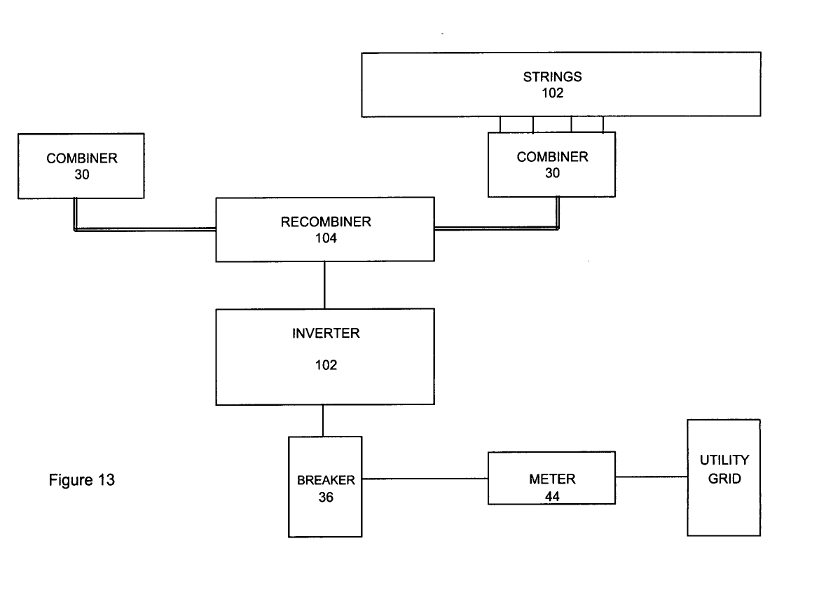

As shown in FIG. 3, the sliding ends 28,29 on each tile 8 allow physical interconnection of the tiles 8 that are electrically connected with one another. Each string of tiles 8 has its own pair of wires that passes through the subroof to the attic below. See FIG. 13. This pair of wires terminates in a combiner box 30 that combines the wires from each string of tiles into a single pair of wires 32, preferably larger copper wires. Several combiner boxes 30 may be used in system 10. A recombiner 104 is used to join multiple combiner boxes such that a single pair of wires 32 carries the power that originates in the cells 4.

For systems 10 connected to a utility power line 40, synchronous inverters 42 are used to produce AC power in synchronization with the power line. The inverter produces power that is of a quality acceptable to the utility company. In these systems 10, the utility company serves as the primary energy storage medium. One side of the synchronous inverter 42 is connected to the DC power, and the other is connected through a meter 44 to a circuit breaker box 36 (FIG. 2).

This connection method allows the utility company to measure the amount of power generated. In systems with only one meter 44, the meter runs backward as energy is produced and excess power is fed into the utility lines 40. When the system 10 generates electricity, the inverter 42 supplies power to meet usage. When usage exceeds production of the system 10, excess power from the utility company is drawn from the utility line 40.

Some systems 10 may incorporate a battery 108 for emergency power or for storage of excess power produced. In addition, a stand-alone inverter or an inverter that operates as a stand-alone inverter or a utility-interactive inverter may be utilized in the system.

The number of cells 4 in the panel 2 determines the output of the tile. A panel of ten 6″-by-6″ cells produces 28 watts at about 5 volts, a panel of twelve 5″-by-5″ cells produces 35 watts at about 7 volts, and a panel of twenty-four 4″-by-4″ cells produces 36 watts at about 12 volts.

Moreover, having thus described the invention, it should be apparent that numerous structural modifications and adaptations may be resorted to without departing from the scope and fair meaning of the instant invention as set forth hereinabove and as described hereinbelow by the claims.

I claim:

1- A system for converting actinic radiation to another form of energy, comprising, in combination:
a surface;
a frame;
a panel sensitive to the actinic radiation;
means to mount said frame on said surface;
means to mount said panel to said frame, said frame exposed to the actinic radiation; and
means to transfer energy from said panel through a chaseway on said frame thence to a power network.

2- The system of claim 1 wherein said panel includes an architectural pigmentation emissive to the actinic radiation.

3- The system of claim 2 further comprising:
means to interconnect a plurality of said frames on said surface, each of said frames having a panel mounted therein; and
means to combine energy from all said panels for output to said power network.

4- A method for converting actinic radiation to another form of energy, the steps including:
forming a panel by connecting a plurality of photovoltaic cells, said panel of photovoltaic cells having a plurality of electrical tabs exiting said panel, each said electrical tab attached to a separate connection wire, each of said connection wires travelling from said panel perpendicular to an edge of said panel and further travelling through a clip that directs said connection wires to separate locations;
lodging said panel in a frame, said frame comprising a recess to receive said panel, separate paths for each said connection wire, a hood adjacent said recess to receive said clip, and means to receive and direct said connection wires along an edge of said frame, said panel and frame comprising a tile;
electrically interconnecting a plurality of said tiles;
imbricating a plurality of said interconnected tiles on a surface exposed to actinic radiation;
combining output from said interconnected tiles; and
feeding said combined output into a power network.

5- An apparatus for converting actinic radiation to another form of energy, comprising, in combination:
a plurality of photovoltaic cells, said photovoltaic cells electrically interconnected with one another and oriented into a panel, wherein output from said panel is directed through a plurality of electrical tabs, said electrical tabs attached to a plurality of connection wires to direct output from said panel, said connection wires routed through a clip; and
a frame, said frame comprising, in combination:
a recess to receive said panel such that a surface of said panel not contacting said frame is planar with respect to a non-recessed portion of said frame, said recess formed by a plurality of cross pieces, said cross pieces defining windows in said frame;
a mounting portion on an edge of said non-recessed portion of said frame, said mounting portion having means to mount a combined frame and panel to a surface;
a plurality of separate paths, each path to receive one said connection wire from said panel; and
a hood to receive said clip from said panel.

6- The apparatus of claim 5 wherein said frame further comprises complemental end portions on two opposing edges of said frame that are not said mounting portion, wherein said complemental end portions engage one another such that a plurality of frames may be placed adjacent one another in a particular orientation.

7- The apparatus of claim 6 further comprising a glass outer sheet adjacent said panel opposite said frame.

8- The apparatus of claim 7 further comprising two layers of ethyl-vinyl acetate adjacent to and on either side of said panel.

9- The apparatus of claim 8 further comprising an aluminum heat sink adjacent to and between said ethyl-vinyl acetate layer and said frame.

10- The apparatus of claim 9 further comprising wind loading clips, said wind loading clips mounted to said means to mount said combined frame and panel to a surface of one said frame and said wind loading clips dimensioned to receive a portion of another said frame.

11- An apparatus for converting actinic radiation to another form of energy, comprising, in combination:
a plurality of photovoltaic cells oriented in a panel, said panel having means to output current through connection wires;
a frame, said frame comprising, in combination:
a recess to receive said panel;
mounting means to mount said frame on a surface, said mounting means on a separate portion of said frame than said recess;
means to separate and direct said connection wires away from said panel; and
clip means to selectively attach one said frame to another said frame.
